(19) United States
(12) Patent Application Publication
(10) Pub. No.: US 2025/0070706 A1
(43) Pub. Date: Feb. 27, 2025

(54) LANE AND PARKING SPACE LINES CONSTRUCTED WITH THIN LAYER SOLAR CELLS TO PROVIDE DC POWER TO ELECTRIC VEHICLE (EV) CHARGING STATIONS

(71) Applicant: Stanley Bagby Howard, Pikesville, MD (US)

(72) Inventor: Stanley Bagby Howard, Pikesville, MD (US)

(21) Appl. No.: 18/442,043

(22) Filed: Feb. 14, 2024

Related U.S. Application Data
(60) Provisional application No. 63/534,808, filed on Aug. 25, 2023.

(51) Int. Cl. H02S 20/20; B60L 53/16; B60L 53/51; G06Q 30/0283; H01L 31/028; H02J 7/35; H02S 40/36

(52) U.S. Cl. CPC H02S 20/20; B60L 53/51; H02J 7/35

(57) ABSTRACT

Road lane and parking space lines are constructed by joining sections of thin-layer solar cells, containing photovoltaic material with electrical conductivity, durability, transparency, and flexibility of material such as graphene. Multiple thin-layer solar cells are joined electrically in series, or with hybrid series parallel connections. Series connections provide high DC voltage to Electric Vehicle charging stations for quick charging. Providing DC power also eliminates a requirement for AC to DC inverters in charging stations. Provided voltage is the sum of voltages from series-connected solar cells. Thin layer solar cell sections may be manufactured with rollers compressing layers of solar cell sections. Compressed layers, including a solar cell layer above an adhesive layer that adheres to thin layer solar cells and road or parking area surfaces, may be constructed using rollers or compactors.

### RELATED U.S. APPLICATION DATA

Continuation of provisional application No. 63/534,808, EFS ID number 48496151, dated 25 Aug. 2023, by inventor applicant named herein, Stanley Bagby Howard.

### REFERENCES CITED

### U.S. Patent Documents

US 20080150289 A1 SYSTEM AND METHOD FOR CREATING A NETWORKED INFRASTRUCTURE DISTRIBUTION PLATFORM OF SMALL FIXED AND VEHICLE BASED WIND ENERGY GATHERING DEVICES ALONG ROADWAYS
US 20080163919 A1 SYSTEM AND METHOD FOR CREATING A NETWORKED INFRASTRUCTURE ROADWAY DISTRIBUTION PLATFORM OF SOLAR ENERGY GATHERING DEVICES
US 20090189452 A1 System And Method For Creating A Networked Infrastructure Distribution Platform Of Small Fixed And Vehicle Based Wind Energy Gathering Devices Along Roadways
US 20090200869 A1 System And Method For Creating A Networked Infrastructure Roadway Distribution Platform Of Solar Energy Gathering Devices
US 20120097238 A1 GRAPHENE-BASED SOLAR CELL
US 20140319913 A1 SYSTEM AND METHOD FOR CREATING A NETWORKED INFRASTRUCTURE DISTRIBUTION PLATFORM OF SMALL FIXED AND VEHICLE BASED WIND ENERGY GATHERING DEVICES ALONG ROADWAYS
US 20150113987 A1 INTEGRATED RENEWABLE ENERGY AND ASSET SYSTEM
US 20170140349 A1 Vehicle Group Charging System And Method Of Use
US 20230406113 A SYSTEM FOR COHESIVELY HARNESSING MULTIPLE FORMS OF RENEWABLE ENERGY IN ELECTRIC VEHICLES AND STATIONARY APPLICATIONS
US 20230420592 A1 SOLAR CELL, MULTI-JUNCTION SOLAR CELL SOLAR CELL MODULE, AND PHOTOVOLTAIC POWER GENERATION SYSTEM
US 20230420674 A1 GRAPHENE, ELECTRODE, SECONDARY BATTERY, VEHICLE, AND ELECTRONIC DEVICE
U.S. Pat. No. 6,081,205 A Electronic Parking Meter And Electric Automobile Recharging Station
U.S. Pat. No. 7,501,713 B2 System And Method For Creating A Networked Infrastructure Roadway Distribution Platform Of Solar Energy Gathering Devices
U.S. Pat. No. 7,741,727 B2 System And Method For Creating A Networked Infrastructure Distribution Platform Of Small Fixed And Vehicle Based Wind Energy Gathering Devices Along Roadways
U.S. Pat. No. 7,800,036 B2 System And Method For Creating A Networked Infrastructure Roadway Distribution Platform Of Solar Energy Gathering Devices
U.S. Pat. No. 8,791,596 B2 System And Method For Creating A Networked Infrastructure Distribution Platform Of Small Fixed And Vehicle Based Wind Energy Gathering Devices Along Roadways
U.S. Pat. No. 4,609,770-A Thin-film solar cell array
U.S. Pat. No. 5,584,940-A Flexible photoelectric conversion module
U.S. Pat. No. 5,674,325-A Thin film photovoltaic device and process of manufacture
U.S. Pat. No. 5,863,354-A Flexible photoelectric conversion module
U.S. Pat. No. 6,380,477-B1 Method of making photovoltaic device

### BACKGROUND

Due to the environmental impacts of consuming fossil fuels and other concerns such as a diminishing supply of such energy sources, in recent years, societal focus, both domestically in the United States of America. and internationally, has increased exponentially on other sources of energy, such as solar energy. Hence, technologies related to vehicles powered by electricity, and other related technologies, such as Electric Vehicle (EV) charging station technology, have become increasingly prominent. A significant use of solar cells could be providing electric power to EV charging stations. Besides advances in EV charging station technology, due to the growth of the EV industry, there have also been significant technological advances in related technologies such as EV battery technology, as well as all battery technologies, such as batteries in EV charging stations, and other related technologies such as solar cells. Likewise, as noted in cross-referenced patents, many methods have been proposed for the generation and use of electric power for electric vehicles. Some of these methodologies may have been implemented; but despite their merit, many may not have been widely implemented yet, possibly due to the significant costs that may be involved in implementing many of these systems.

Though thin layer solar cells are not limited to using only one photovoltaic material, providing electric power to EV charging stations could be implemented using thin layer solar cells incorporating a photovoltaic material such as graphene, i.e., a hexagonal lattice allotrope of carbon that can be as thin as one layer of atoms. Patents such as US-20120097238-A1 provide a technique for manufacturing graphene. Likewise, patents such as US-20230420674-A1 provide a detailed description of how graphene batteries could be manufactured and used. In a graphene lattice, each atom is bonded to adjacent atoms by three one dimensional sigma bonds and a single multidimensional pi bond, such as described in the article “Experimental Review of Graphene”, by Daniel R. Cooper, Benjamin D'Anjou, Nageswara Ghattamaneni, Benjamin Harack, Michael Hilke, Alexandre Horth, Norberto Majlis, Mathieu Massicotte, Leron Vandsburger, Eric Whiteway, and Victor Yu, in the International Scholarly Research Notices, vol. 2012, published by Hindawi, London, on 26 Apr. 2012. Due to such physical and chemical properties, an electrically conductive material such as graphene is an excellent electrical conductor, though other photovoltaic materials could be incorporated into thin-layer solar cells as described in this patent application. Patents already exist with claims for using solar cells and other power-generating technologies such as geothermal heat pumps and thermocouple banks to supply power to EV recharging stations. However, no existing patent has claims of exactly how roadway lines and parking space demarcation lines could use thin-layer solar cells incorporating a photovoltaic material, such as graphene, to provide colored, or uncolored lines, of thin layer solar cells connected electrically in series to demarcation road lane and lines to supply DC electrical power to EV charging stations, as detailed in this patent application. Furthermore, no patents exist with claims for using such thin-layer solar cells connected in series for parking space demarcations lines to supply Direct Current (DC) power to EV charging stations in areas such as parking lots, road pull over areas, and street parking, as detailed in this patent application. Likewise, additional inherent electrically conductive characteristics of a material such as graphene, such as its electrons attracting ions in rainwater, could further enhance the efficacy of using a material such as graphene in solar cells, as described in the article “Graphene Could Help Generate Power From Rain”, by Charles Q. Choi, published by the Institute of Electrical and Electronics Engineers (IEEE) Spectrum, New York, on 6 Apr. 2016.

Systems as described in this patent application could be implemented with newly developed thin layer materials other than graphene. Graphene is described as two dimensional (2D) because it is manufactured in a carbon lattice that may be just one atom thick. This 2D lattice possesses highly desirable qualities for industries such as electronics, as well as for experimental research. These desirable qualities include super conductivity, extreme durability many times that of steel, light weight, and transparency, because for 2D applications, it can be only one atom thick. Rather than carbon, such 2D materials with such desirable qualities could be made of other elements such as silicon and germanium and synthesized materials using combined elements, such as what is called doping in electronics. Such different material could be used for a semi-transparent painted outer layer of solar cells exposed to sunlight, an inner layer of solar cells connected in series, and a bottom layer of a durable material adhering tightly on its top side to a solar cell layer and on its bottom side adhering tightly to a road or parking area surface. Likewise, new techniques are being developed to make graphene less expensive, such as techniques being explored by research at Rice University, as described in an article with the header “Graphene typically costs $200,000 per ton. Now, scientists can make it from trash.”, by Matt Davis, in the Jan. 31, 2020, edition of the web newsletter Big Think.

### SUMMARY OF THE INVENTION

This invention proposes using road and parking space lines constructed of thin-layer solar cells, containing a material with the electrical conductivity, durability, insulating capability, transparency, and other useful qualities of a material such as graphene, to provide voltage and power to Electric Vehicle (EV) charging stations, such that higher voltages with series connections of solar cells and higher power with parallel connections in hybrid series parallel configurations of solar cells, could facilitate fast charging more economically than other methods currently implemented to provide voltage and power to EV charging stations.

In the context of this patent application, providing power to EV charging stations refers to providing power directly to electric vehicles connected to charging stations or providing power to and from batteries connected to EV charging stations. These batteries could be connected to other batteries providing power to one or multiple EV charging stations. Such batteries could be connected to other batteries in series or parallel, depending on the design of such a bank of batteries and the specifications of the batteries that are used, such as charging capacity and efficiency, charging amperage, and discharge time, etc. Preferably a battery or bank of connected batteries would provide a voltage that matches the voltage provided by a line array of solar cells. Additionally, connections of solar cell arrays to EV charging station batteries could be facilitated by electrical components such as controller devices.

Many patents provide detailed descriptions of solar cell road lines constructed out of thin layer solar cells. However, such patents may not provide practical and economically feasible descriptions of how such systems could be implemented. For example, a system employing windmills along roadways could be expensive, despite its considerable merit and the reliability of wind power. Likewise, a system using transmitting devices and other related equipment, such as described in Patent US-20170140349-A1, might be expensive for widespread distribution, despite its significant usability. Additionally, if a proposed implementation provides Alternating Current (AC) power to EV charging stations, further expense could be incurred by requiring AC to DC electric power inverters in EV charging stations, though both DC power to EV charging stations without inverters and AC power to EV stations with inverters could supply power to EV charging stations as described in this patent application. Most EV charging stations, as currently implemented, require AC to DC voltage inverters because provided power typically is AC rather than DC. Furthermore, at remote locations AC power from conventional power sources such as power lines might not be readily available.

Though thin layer solar cells as described in this patent application could contain graphene or other photovoltaic materials currently available, that have similar desirable qualities as graphene and its derivatives, newer materials with these desirable properties, such as significant electrical and thermal conductivity, insulating capability, durability, flexibility, and other desired qualities, including paintable transparency, could also be less expensive than materials currently available, or have better desired characteristics. Such newer materials could be used to implement a system such as described in this patent application. Likewise, as previously noted, the cost of photovoltaic materials such as graphene have been decreasing with new manufacturing techniques and may decrease even more in the future.

Furthermore, because power sources for most EV charging stations, as currently implemented in many applications, are AC rather than DC, using solar cells connected in series as described in this patent application could have significant cost advantages. For example, as previously noted, AC to DC electric power inverters would not be required in EV charging stations to use DC power for batteries in EV charging stations that collect provided DC power, if not use it directly, that is provided by lines of thin-layer solar cells as described in this patent application. Such power transforming components could be incorporated into charging stations to convert backup AC power to DC, as a backup to provided DC power when economically feasible. Likewise, EV charging stations could incorporate transformers to convert provided high DC voltage such as required for Level 3 electric vehicle charging to lower voltages such as required for Level 1 and Level 2 charging, though in many cases such as at remote locations, EV charging stations might provide only fast charging. Additionally, because DC current from solar cells connected in series, and possibly in hybrid configurations with parallel connections connected with series connections of solar cell segments for increased current and resulting power, as well as series connections for a complete circuit, would generate lower amperage than AC current, wires supplying DC power from solar cells could be thinner than wires conducting higher AC amperage, such as amperage generated by parallel electrical connections. High voltage DC power provided by conventional means such as electrical wire could require more insulation to prevent the undesirable impacts of higher voltage, such as generating more heat at higher voltages. However, a material with qualities such as those of graphene, could provide better insulating qualities as well as superconductor qualities, such as described in “Physicists discover important new property for graphene”, by Elizabeth Thomson, published in Massachusetts Institute of Technology (MIT) News On Campus and Around the World, Cambridge: MIT Press, on Feb. 8, 2021.

An important advantage of using solar cells in series with series connections and parallel connections in hybrid series parallel configurations is that longer lines of solar cells connected in series could generate higher voltages. Faster charging requires higher voltage than standard 120 volts, such as required for slower Level 1 charging. Higher voltages, such as more than 200 volts as required for Level 2 charging, may be available at locations such as grocery store parking lots, or at other locations where higher voltage connectors may be available, such as in the garages of electric vehicle owners, etc. High speed Level 3 charging may require from 400 volts DC to 1000 volts DC, depending on factors such as the type of connector required by specific types of electric vehicles. Faster charging time has obvious advantages such as user convenience in less time expended for recharging and less competition for available charging stations. Despite some voltage loss and a resulting power loss in DC power when transmitted over long distances, compared to such losses in AC power when transmitted over long distances, such losses might be minimal in distances traversed by a line of series connected solar cells providing DC power to EV charging stations.

Besides previously described cost advantages, EV charging stations powered by thin layer solar cells, as described in this application, could also have additional significant advantages over EV charging stations powered by AC power. For example, as previously noted, EV charging stations could be provided at remote locations where significant AC power sources might not be readily available. Nevertheless, AC power from conventional power sources such as AC power lines could be used to supplement EV charging stations powered by DC power sources, such as thin layer solar cells connected in series and hybrid series parallel configurations.

Additionally, series-connected thermocouples, such as described in US 20230406113 A1, and other power sources such as geothermal heat pumps, such as detailed in patent US 20150113987 A1, could supplement EV charging stations powered by DC power sources such as thin layer solar cells. Despite possible significant advantages of systems that use thermocouples for EV charging stations, the use of thermocouples to generate DC power as described in this patent application was not detailed in this application because the low voltage currently generated by individual thermocouples with current thermocouple technology could make using thermocouples connected in series to provide DC voltage to EV stations prohibitively expensive, as described in this patent application, because many thermocouples might be required to provide 120 volts and even higher voltages of 400 volts or more for fast charging. Of course, if thermocouple technology were to improve, such that more voltage could be generated by a lower number of thermocouples connected in series, it might be feasible to use such devices with road or parking line demarcation lines to generate DC power as described in this patent application, which describes using solar cell technology. Note also, as previously noted, despite the increased cost of using AC-powered EV charging stations, particularly the need for inverters in charging stations, there might be efficacy in using conventional AC power sources as a supplement or backup for DC power supplied by sources such as thin layer solar cells.

Additionally, as noted, for EV charging stations at some remote locations, supplemental AC power sources or usage of other related technologies such as geothermal heat pumps might be impractical for power generation at night or other times when solar energy is diminished. This might be for many reasons, such as economic or environmental concerns. At such remote locations, EV charging stations could be equipped with additional batteries for storage of DC power generated by thin layer solar cells when solar energy is available. Likewise, lines of thin layer solar cells connected in series, as well as with hybrid parallel connections for higher current and power than all series connections, with series connections of such hybrid configurations, to provide DC power to such remote locations could be made longer so that more DC voltage could be generated when solar energy is available. Furthermore, the performance of solar cells containing a photovoltaic material such as graphene could be improved significantly with technological advances such as by using material such as perovskite solar cells (PSC) integrated with graphene, such as described in the article “The roles of graphene and its derivatives in perovskite solar cells: A review” by Kaiwen Gong, Jichao Hu, Nan Cui, Yunzhou Xue, Lianbi Li, Gen Long, and Shenghuang Lin, published in Science Direct, Materials and Design, Volume 211, 1 Dec. 2021, 110170.

Safety would be a very important significant concern in an electrical a system that provides high voltage DC power to EV charging stations such as described in this patent application, that is, using line arrays of series and hybrid series parallel configuration of thin layer solar cells on roadways and in parking areas to provide voltage and power to EV charging station batteries. However, the dangers imposed by such a system in which human contact might be possible could be well mitigated by safety measures such as fuses, isolation switches, and grounding, such as are often used in existing electrical systems. This patent application does not propose new methods for the design and use of such commonly implemented safety features, or make claims for such, but rather proposes that a system such as proposed in this patent application could be made more feasible by incorporating such existing safety features.

However, safety concerns can be mitigated with features as described in this patent application, which are asserted in claims of this application. Specifically, if a material such as graphene, which has significant durability and insulating capability, were incorporated into thin layer solar cells used to construct series-connected lines of thin layer solar cells such as described in this application, this could provide further protection against human exposure to the high voltage and current in such an electrical system. Additionally, if a highly durable adhesive material were used to adhere sections of thin layer solar cells to a road or parking area surface, such as an epoxy resin, this could provide additional durability and insulation protection.

### BRIEF DESCRIPTION OF DRAWINGS

FIG. 1, i.e., Drawing 1: Manufacturing Process of Solar Line Sections, depicts a process facilitated by rollers for manufacturing sections or strips of thin-layer solar cells that could be placed on a road or parking space surface. As a contiguous whole, additively based on total number solar cells connected in series, layered solar cells could be used to create road lane demarcation lines or parking space demarcation lines, or rows of parking lot spaces. As depicted, layers of these solar cell sections could contain an outer layer of transparent or semitransparent color-imbued material exposed to sunlight during daylight hours; and the Direct Current (DC) electricity generated by these solar cells could be stored in a battery or battery bank supplying EV charging stations. Below a semi-transparent color-imbued layer, roller-pressed layers would include additional layers such as a positive and negative substrate layer connected in series to generate DC power. Below these electricity-generating layers, another layer could contain an adhesive material that could be pressed onto a road or parking space surface.

FIG. 2, i.e., Drawing 2: Series Connections of Solar Cells, provides additional details of series connections of series-connected lines of thin-layer solar cells to EV charging stations. As depicted, sunlight would activate thin layer solar cell lines made of a flexible thin-layer material such as graphene, though photovoltaic materials other than graphene could be used in such thin layer solar cells. As shown, solar cells would be connected in series, that is, the positive lead of each solar cell would be connected to the negative terminal of the next cell, such that provided voltage would be the sum of each solar cell connected in series. Preferably through a device such as an electrical controller, a line of series-connected solar cells would be connected to batteries providing power to EV charging stations. Typically, connections from lines of solar cells would be to one or more batteries connected to EV charging stations.

FIG. 3, i.e., Drawing 3: Hybrid Series Parallel Connections of Solar Cells, depicts how thin layer solar cells could be connected in series and parallel configurations using multiple thin layer solar cells connected in series and series parallel configurations. As described in the detailed description of this figure, series connections could provide higher DC voltages for quick charging connections at EV charging stations, such as for Level 3 charging. Additionally, parallel connections could provide more current and therefore more power to charging stations for faster charging of batteries, depending on other factors such as the charge capacity and charging efficiency of batteries connected to EV charging stations, etc.

FIG. 4, i.e., Drawing 4: Safety Features of Series Solar Cell Circuit, depicts safely features that could be incorporated into circuits constructed of thin layer solar cells connected in series and in series parallel configurations such as described in this patent application. Safety features such as isolation switches and grounding as depicted in this drawing would be required in any electrical circuit using components such as batteries and EV charging stations, as described in this application. Furthermore, such safety features would be especially necessary in a circuit providing high voltages in areas such as on roadways and in parking areas, where human contact might be likely.

FIG. 5, i.e., Drawing 5: Application to Road Processes, depicts a process for adhering a line constructed of series-connected thin-layer solar cells to a road or parking lot surface by employing large rollers machines or hand-pushed compactor machines that could be hand-pushed by road workers or otherwise provided by road construction equipment operated by road crew machinery operators. This figure provides additional details illustrating three functional layers incorporated into thin-layer solar cells, that is, a semi-transparent optionally color-imbued outer layer facing sunlight, a solar cell layer incorporating a flexible, thin-sheet photovoltaic material such as graphene, though not limited to this material only, and an adhesive layer facing the road or parking lot surface for adherence to a road or parking space surface as well as the solar cell layer. A roller or compactor could push the adhesive layer down, thereby adhering the solar cells sections or strips onto the road or parking space surface.

FIG. 6, i.e., Drawing 6: Layout of Lines on Road, depicts how vehicle lane boundary demarcation lines made of thin-layer solar cells could be configured on roadways, as described in listed existing referenced patents. As depicted, lines of thin-layer solar cells could be used to provide lines on the outer side of lanes going in opposite direction, i.e., the right side of the road depending on direction of travel, and as center lines or other lane separators for an additional source of DC power.

FIG. 7, i.e., Drawing 7: Layout of Line Section in Parking Lot, depicts how thin layer solar cell lines in series could be used to demarcate parking lot or street parking spaces, as color-imbued lines demarcating parking spaces, to supply DC power to EV charging stations. As noted in the detailed description, lines could be made of layered solar cells lines such as used for roadway lines. Likewise, such thin layer solar cells lines in parking areas could be constructed using rollers or other road construction equipment such as compactors.

FIG. 8, i.e., Drawing 8: Detail of Solar Cells Line in Parking Lot, depicts additional details of how lines of thin layer solar cells, containing a material such as graphene, though not limited to this photovoltaic material, could be configured in rows of cells connected in series to EV charging stations. As depicted, facing rows, i.e., adjacent rows, could be electrically connected with opposite polarity from adjacent rows, though adjacent rows could be configured with the same polarity.

FIG. 9, i.e., Drawing 9: Detail of Solar Cells Line in Street Parking Spaces, depicts additional details of parking space demarcation lines made of thin-layer solar cell lines such as for on street parking. Likewise, such parking space lines could be connected in series to EV charging stations, which could include monetary charge meter parking space kiosks interfaced with software for EV charging stations.

### DETAILED DESCRIPTION OF THE INVENTION

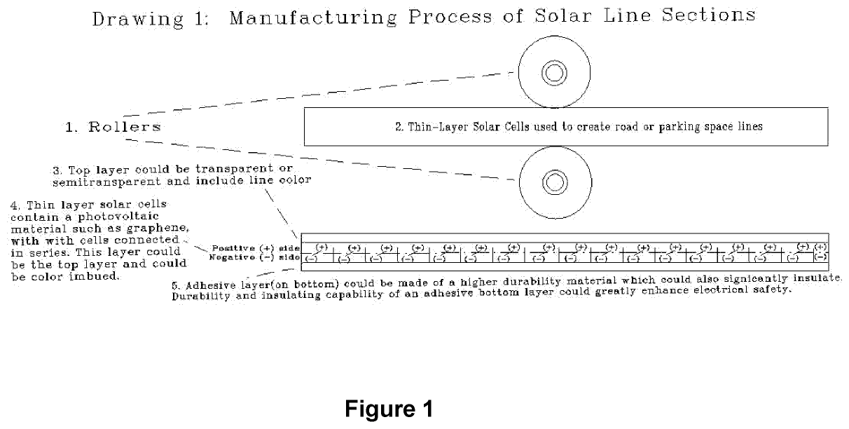

As depicted in FIG. 1, that is, Drawing 1: Manufacturing Process of Solar Line Sections, sections or strips of thin-layer solar cells could be manufactured with a manufacturing process such as using rollers to press layers of material together. As depicted in Detail 1, such a manufacturing process could employ machinery with one or two rollers above and below thin layer solar cells, such as depicted in Detail 2. Manufactured solar cells sections would include a layer of solar activated electrically conductive material, such as depicted, a transparent or semitransparent top layer such as depicted in Detail 3, a solar cell layer of solar cells connected in series such as depicted in Detail 4, and a bottom layer of adhesive material such as depicted in Detail 5. As noted in Detail 3, the top layer could be transparent or semitransparent to allow sunlight penetration to solar cells in a middle layer and might be color imbued. As noted in Detail 4, the solar cells layer could contain a photovoltaic material such as graphene. Furthermore, such layers could be in various configurations. For example, colors such as yellow, white, or green, or no color, could be incorporated into a transparent top layer or into a solar cells layer.

As noted in Detail 4 of FIG. 1, positive and negative poles in solar cells could be joined layer in series, that is, with opposite poles joined, or negative to positive as depicted to generate voltage from each cell additively. Likewise, series connections could join multiple sections to generate higher DC voltage than might be generated by a single solar cell section, or strip.

As depicted in Detail 5 of FIG. 1, a durable bottom layer could include a durable adhesive material with an adhesive material on its bottom side for adherence to a road or parking space surface. Such an adhesive material would have to be imbued into this bottom layer to adhere tightly onto other layers, such as a middle solar cell layer, as well as a road or parking space surface. Likewise, as noted, if such an adhesive layer were a material with significant insulating capability, as well as great durability, such as an epoxy rosin, this could enhance safety of the system.

Although rollers are used extensively in the manufacture of materials such as depicted in FIG. 1, and in techniques employing rollers to manufacture thin-layer solar cell sections or strips, such as described numerous publications and in Patents U.S. Pat. Nos. 5,584,940-A, 5,863,354-A, and 6,380,477-B1, or for the manufacture of other materials such as cold-pressed stainless steel, no patents describe the use of such rollers to manufacture thin layer solar cells sections, or strips, that could be used to generate DC power when connected in series to form roadway or parking space demarcation lines, such as described in this patent application.

Patents such as Patent U.S. Pat. No. 4,609,770-A also provide detailed descriptions of techniques whereby thin-layer solar cells could be joined electrically in series, and such techniques could be used to join thin-layer solar cells as described in this patent application. However, such descriptions do not provide a detailed description of the different layers of thin-layer solar cells incorporating a photovoltaic material such as graphene, though not limited to this material, and an adhesive layer, such as depicted in FIG. 1.

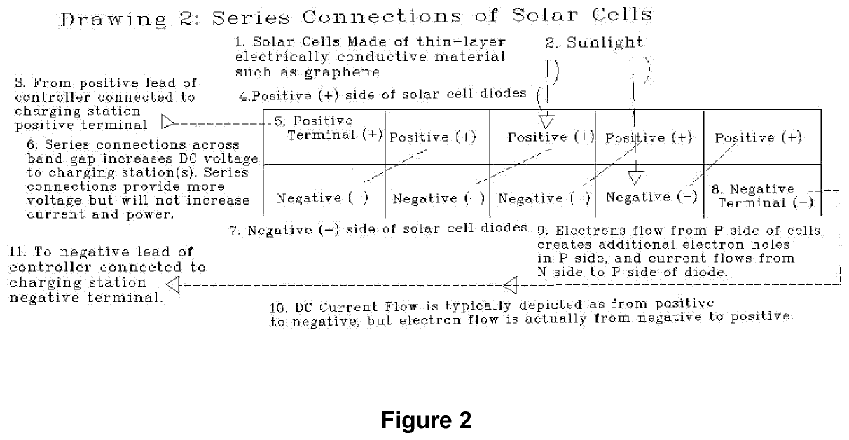

FIG. 2, that is, Drawing 2: Series Connections of Solar Cells, provides additional details of how lines constructed of thin layer solar cells could be joined in series, with individual cells in sections joined in series. This layer of solar cell sections would consist of an array of solar cells, containing a photovoltaic material such as graphene, as noted in Detail 1, exposed to sunlight, as depicted in Detail 2, joined by a means such as described in Patent U.S. Pat. No. 4,609,770-A. The only necessity for such a configuration of such thin-layer solar cells connected to EV charging stations to generate DC power would be that solar cells and sections or strips of solar cells be connected in series. As depicted by Detail 5, such series connections could be facilitated by a connection to the positive side of the first solar cell, or section of solar cells, in a line of solar cells, from to the positive terminal of batteries connected to EV charging stations, preferably via a controller, such as depicted by Detail 3. Likewise, Detail 8 depicts a lead from the negative terminal of batteries in EV charging stations to the negative side of the last solar cell in a DC voltage line of series-connected solar cells, preferably via a controller, such as depicted by Detail 11. Detail 9 notes how solar cells could generate electricity, using solar cells of a design such as described in Patent US 20230420592 A1.

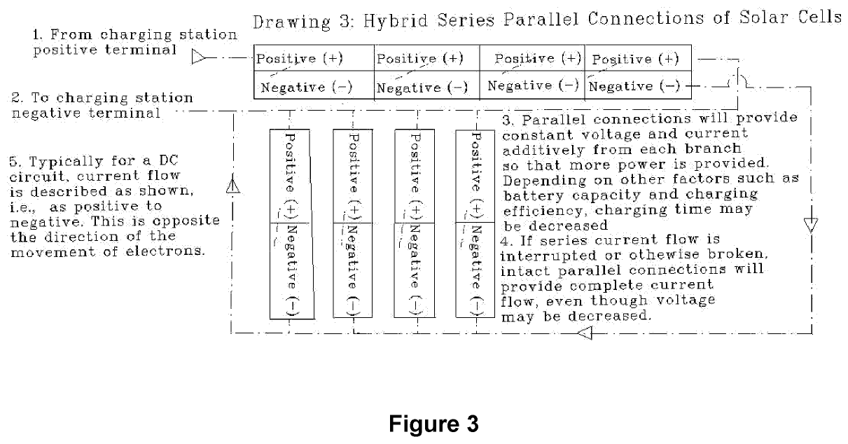

As noted by Detail 10, in a DC circuit, typically current flow is depicted as from positive to negative. However, the flow of electrons is from negative to positive; and current flow could be depicted as in the opposite direction. Detail 6 notes that series connections across each solar cell connected in series could increase voltage additively for total voltage provided to EV charging stations. As noted, series connections of solar cells will additively increase voltage provided to EV charging station batteries and will, therefore, facilitate faster charging by providing higher voltages required for faster charging of high voltage batteries, or battery banks providing voltage matching provided voltage, or simply for fast charging of batteries in electric vehicles connected to EV charging stations. As noted, though, series connections will not provide current additively and therefore higher power as could parallel connections, and could possibly decrease charging time of batteries, as described in the detailed description of FIG. 3.

Total resistance in a line of solar cells would be determined by the following formula, using reciprocals of resistance values, with 1\Rₜₒₜₐₗ representing computed total resistance, R₁ representing resistance in the first series segment, R₂ representing resistance in the second segment, R₃ representing resistance in the third segment, Rₙ representing resistance in the last segment, and so on:

$$1 / {R}_{total} = 1 \backslash {R}_{1} + 1 \backslash {R}_{2 +} 1 \backslash {R}_{3} + … + 1 \backslash {R}_{n}$$

Ohms law, that is, V=IR, is that voltage equals current times resistance. With a constant voltage across a battery, total current provided by series connections is constant in a series circuit. So, as noted in Detail 6, provided power from series connections would not be enhanced by higher current for quicker charging of EV charging station batteries, though this might enhance charging times of higher voltage batteries providing voltage to or from EV charging stations.

As described in FIG. 3, that is, Drawing 3: Hybrid Series Parallel Connections of Solar Cells, parallel connections could provide higher current and thereby facilitate faster charging of batteries in EV charging stations, depending on other factors such as the charge capacity of charging station batteries and their charging efficiency. A rudimentary determination of the time required to charge a battery can be is determined by the formula: T=Ah/A. In this formula, Ah represents Ampere hours, that is, the number of hours a battery will provide a specified number of Amperes of current. For example, a battery that provides 200 Ah could provide 200 Amps of current for one hour, 100 Amps for 2 hours, 50 Amps for 4 hours, 10 Amps for 20 hours, and so on. In this formula, A represents the amperage required to charge the battery. The amperage required to fully charge a battery is nominally computed as 10% of the Amp hours rating of the battery, i.e., the Ah, of the battery (or batteries in a bank of batteries). For example, the required charging amperage of a battery with an Ah of 100 Amp hours would be 10 Amps to fully charge, and a battery with an Ah of 50 Ah could require 5 Amps, etc. Devices, such as an electric vehicle battery, that are attached to an EV charging station batteries will consume the Amp hours currently stored in the EV charging station batteries. As detailed in the article “The Power of Electric Car Battery Amp Hours: How Much Juice Does Your EV Really Have?” by Gloria W. Hughes in the Dec. 14, 2023 edition of Electric Car Wiki, an electric vehicle car battery typically will have a battery that can store from 30 kWh to 100 kWh. For example, as detailed in this article, the battery of a Tesla Model S might provide 100 kWh for a range of more than 400 miles on a full charge. Etc.

However, though series connections can provide higher voltages for faster charging, higher voltage alone will not facilitate faster charging of EV charging station batteries, because, as previously noted, series connections will not increase total current provided to the batteries in charging stations and, therefore, will not facilitate faster charging of batteries such as could be provided by parallel connections, such as described in FIG. 3. This is because faster charging is facilitated by current and voltage by the formula: P=IV, that is, current multiplied by voltage, or with IR substituted for voltage, P=I²R. Furthermore, for a more accurate measurement, determining the charging time of a battery is more complex than just using its amp hours and the amperage it requires for charging. For example, charge time is also determined by other battery ratings, such as its charging efficiency and depth of discharge, which relates to how much of a battery's capacity is being discharged relative to its charge capacity in Amp hours, etc.

FIG. 3 depicts a segment of a possible configuration of thin later solar cells with both series and parallel connections. Using both types of electrical connections in a line of series connected thin layer solar cells containing a photovoltaic material such as graphene could provide advantages from both types of connections in power provided to batteries providing power to and from EV charging stations. As depicted in Detail 1 and Detail 2, wired connections could be provided from positive and negative terminals of batteries providing power to and from EV charging stations. As noted in Detail 3, unlike series connections, parallel connections will provide a constant voltage across each parallel branch and current additively across parallel branches by the formula:

$${I}_{total} = {I}_{R 1} + {I}_{R 2} + {I}_{R 3} + … + {I}_{R n}$$

Since the voltage provided to or from batteries in EV charging stations is constant, the current across each branch can be computed with Ohms low, for example, with a formula such as this for current in the first branch: I_{R1}=V_{R1}/R₁, using the resistance of the branch and provided voltage, etc.

Circuits that are wired exclusively in series have the disadvantage such that if there is a break in the series circuit, all voltage and current provided by the circuit is interrupted. However, as noted in Detail 4 of FIG. 3, if there is a break in one of the series circuits in a hybrid series parallel configuration, parallel circuits in a still complete circuit may still provide power, even though provided voltage will be decreased by the series part of the circuit in which power is interrupted.

As previously noted, as noted by Detail 5 of FIG. 3, in a DC circuit, typically current flow is depicted as from positive to negative. However, the flow of electrons is from negative to positive; and current flow could be depicted as in the opposite direction.

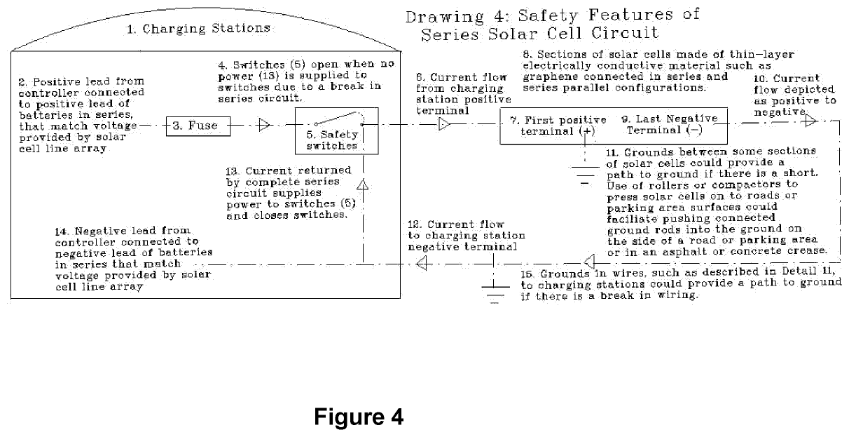

FIG. 4, that is, Drawing 4: Safety Features of Series Solar Cell Circuit, depicts safety features, such as isolation controllers, fuses, switches, and grounding, that should be incorporated into any electrical circuit, especially a circuit providing or using high voltages. As described in this patent application, high voltage from series connections and, in some cases, additional current from parallel connections in series parallel configurations could be constructed with thin layer solar cells connected in series and in series parallel configurations to provide DC power to EV charging stations. Furthermore, systems that use conventional banks of solar cells, such as a grid on a roof supplying power to a residence and the electrical grid require such safety measures.

Detail 1 of FIG. 4 indicates that EV charging stations as described in this patent application could contain safety components such as a controller, fuses, safety isolation switches, and grounds. Detail 2 indicates, with current flow as depicted from positive to negative, that is, opposite the flow of electrons, a lead to safety isolation switches would be connected to a positive polarity lead from EV charging station batteries, preferably via a controller to minimize electrical back flow to or from charging stations. Besides isolation of connections to and from EV charging station provided by a controller, additional electrical safety could be provided by fuses, such as depicted by Detail 3. Detail 5 depicts safety switches that could also electrically isolate a charging station. As shown, such switches would normally be pulled closed by power returned from a complete circuit, such as indicated by Detail 13. Detail 4 notes that such isolation switches would open when there is no return power provided by a complete circuit. Detail 14 indicates that a series circuit provided power by an array of thin layer solar cells would complete the electrical circuit with a connection to a negative lead of batteries providing power to or from EV charging stations, preferably via a controller to minimize electrical backflow.

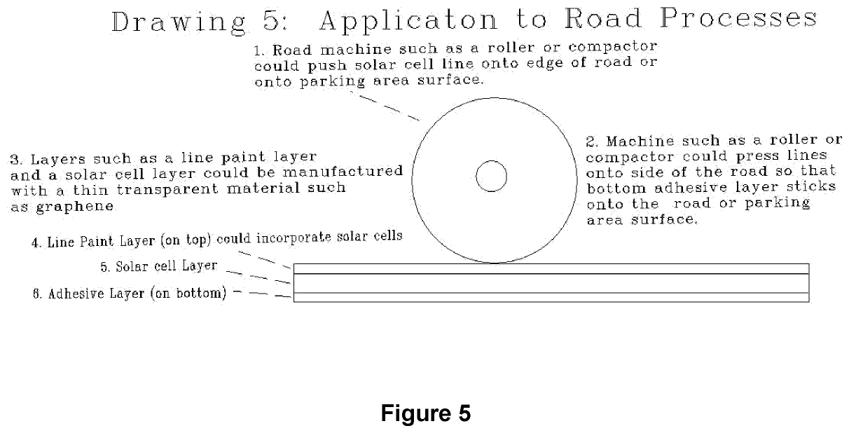

Detail 11 and Detail 15 of FIG. 4 indicate that additional safety could be provided by grounding in an electrical circuit constructed of thin-layer solar cells. Specifically, Detail 11 indicates that grounding could be provided between sections of solar cells to provide grounding if there is a short in an array of solar cells. As noted, use of rollers such as noted in Detail 1 of FIG. 5, or a hand-operated compactor such as noted in Detail 2 of FIG. 5, could facilitate pushing a ground rod into the ground next to a road or parking area; such grounds could be much safer below durable materials in specified thin layer solar cell sections or between specific sections, etc. Detail 11 also notes that grounding in asphalt or concrete road surfaces could be facilitated by inserting grounding rods at specific locations such as on the edge of roads or parking area where earth ground is readily accessible. Likewise, grounds could be inserted into construction creases in parking lots, or roads, such as between concrete and asphalt or sections of asphalt or concrete such that grounding wire or rods could penetrate earth ground without having to make a large hole in the road or parking area surface. Detail 15 indicates that grounding could also be provided in circuit wires to mitigate a short or break in wiring, such as described in Detail 11. Also note that “green” technology could be further enhanced by use of renewable materials such as cork to encase grounding wires.

Additional details in FIG. 4 provide details for an electrical circuit with safety features. Detail 2 indicates that as depicted current flow is from the positive side of polarity in EV charging station batteries; and Detail 7 indicates that wiring from an EV charging station would be connected to the first positive lead in an array of series-connected solar cells, such as described in Detail 8. Typically, in a DC circuit, as previously noted, current flow is described as from positive to negative and the “hot” lead is the positive lead, etc., as reiterated in Detail 10. Likewise, Detail 12 indicates that a return connection is wired to a negative lead in EV charging batteries; and Detail 9 indicates that return wiring would be connected to the negative lead in the last solar cell an array of series-connected solar cells.

Batteries providing power to and from EV charging stations could be configured with a wide variety of series and parallel connections. However, as noted in Detail 2 and Detail 14, for optimal functionality, multiple batteries would preferably be connected such that they will provide, and be charged with, a voltage that matches DC voltage provided by the array of series-connected thin-layer solar cells, that may incorporate parallel connections in a hybrid series parallel configuration, such as might be used in battery connections of multiple batteries, etc. As noted in Detail 2 and Detail 14, connections to EV charging station batteries could be facilitated by a controller that connects a solar cell array to EV charging station batteries; such controllers could enhance system safety and protect circuit components.

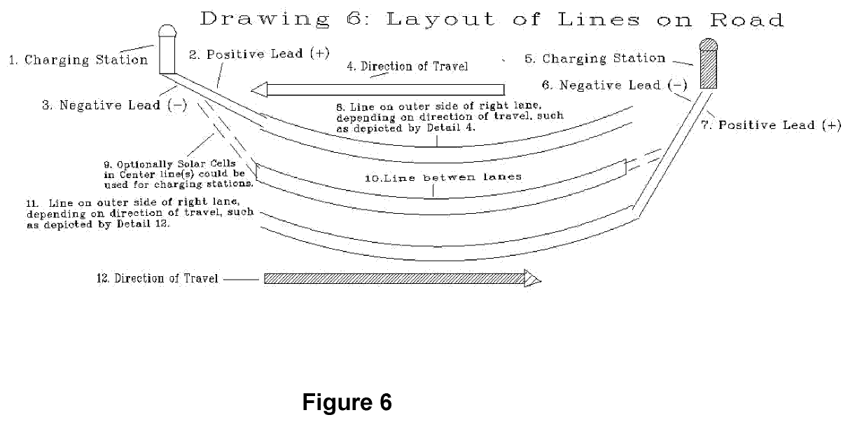

As depicted in FIG. 5, that is, Drawing 5: Application to Road Processes, a roller or compactor, such as machines commonly used in road construction, could apply thin-layer solar cell lines on to a road or parking area surface, such as depicted in Detail 1. Such lines would be pressed onto a roadway or parking area surface as depicted. Layers of such lines could contain an outer layer of transparent color-imbued material exposed to sunlight during daylight hours. DC electricity generated by these solar cells could be stored in battery banks supplying EV charging stations or be provided directly to the batteries of electric vehicles connected to the EV charging stations. Below a semi-transparent colored layer, such as depicted by Detail 4, a thin layer solar cell section or strip, such as depicted by Detail 5, could include additional layers such as a positive and negative substrate layer connected in series to generate DC power. Below these electricity-generating layers another layer could contain an adhesive material, such as depicted in Detail 6, that would be pressed by a road equipment roller or compactor onto a road or parking area surface, such as described in Detail 2, as well as onto a solar cells layer, depicted in Detail 5. Such sections or strips could be connected in DC series with a negative lead and a positive lead connected to EV charging stations, facilitated by DC batteries to store and provide DC power, such as depicted in FIG. 6.

Existing patents that provide descriptions of thin layer sections or strips of solar cells, such as described in Detail 3 and Detail 5 of FIG. 5, with a durable, electrically conductive, and flexible material such as graphene, include patents U.S. Pat. Nos. 5,584,940-A, 5,674,325-A, 5,863,354-A, and 6,380,477-B1. However, few if any descriptions of such thin layer solar cell sections or strips provide detailed description of the layers of such solar cells strips and how they could be adhered on to a road or parking area by using rollers or compactor, such as those commonly used in road construction, as noted in Detail 1 of FIG. 5, an as described in this patent application, to push a bottom adhesive layer on to the road surface or parking area surface and, if possible, join negative and positive leads from multiple strips, possibly using a crimping technique such as described in Patent U.S. Pat. No. 6,380,477-B1. Additionally, as described in Detail 11 and Detail 15 of FIG. 4, construction rollers and compactors could facilitate pressing ground wire into ground earth at locations where this is practical and otherwise feasible.

FIG. 6, that is, Drawing 6: Layout of Lines on Road, depicts how thin-layer solar strips could supply DC power to EV charging stations. As depicted in Detail 2 and 3, and Detail 6 and Detail 7, positive and negative leads connected to thin-layer lines of solar cells could be connected to an EV charging stations, as depicted by Detail 1 and Detail 5, depending on the direction of travel, such as depicted by Detail 4 and Detail 12. Detail 8 and Detail 11 depict the right lane of a road, depending on direction of travel, such as depicted by Detail 4 and Detail 12. Many patents, such as Patents US-20080150289-A, US-20080163919-A1, US-20090189452-A1, US-20090200869-A1, US-20140319913-A1, U.S. Pat. Nos. 7,501,713-B, 7,741,727-B2, 7,800,036-B2, and 8,791,596-B2, provide detailed description of systems in which thin-layer solar cells, such as in strips or a paint spray of such photovoltaic material, could be incorporated into lines of solar cells on roadways. However, these patents do not describe details of how such thin layer strips made of a photovoltaic material, such as graphene, though not limited to this material only, could be used solely to supply DC power to an EV charging station, as described in this patent application, as a line on the right or left sided of a road, or between lanes, such as depicted by Detail 9. Likewise, such sections or strips of thin-layer solar cells could be used to provide lines between lanes or a center lane, etc., though such a thin layer solar cell array might require more overhead than such an array on the side of a road at a location such as prior to a rest stop or road pullover, because leads might have to go across a lane to reach a charging station.

Furthermore, though related similar existing patents have considerable technological merit, many propose using such thin-layer solar cell arrays for lane lines in combination with elaborate and possibly expensive systems such as a system employing windmills along a roadway in combination with thin-layer arrays of solar cells in lines, rather than a simpler system with DC connection to an EV charging station, such as depicted in FIG. 6. Many of these systems also incorporate AC to DC inverters for power provided to EV charging stations, etc. Line arrays of thin-layer solar cells as depicted in FIG. 6 could readily be employed at a location such as a rest stop or a more remote roadside pullover area, with solar cell line arrays connected to EV charging stations at such locations.

Road lines or parking space lines could be imbued with color such as white or yellow, depending on the usage of the line. Also, besides color, road lines created from solar cells sections or strips could be imbued with other materials such as reflective or skid-resistance material.

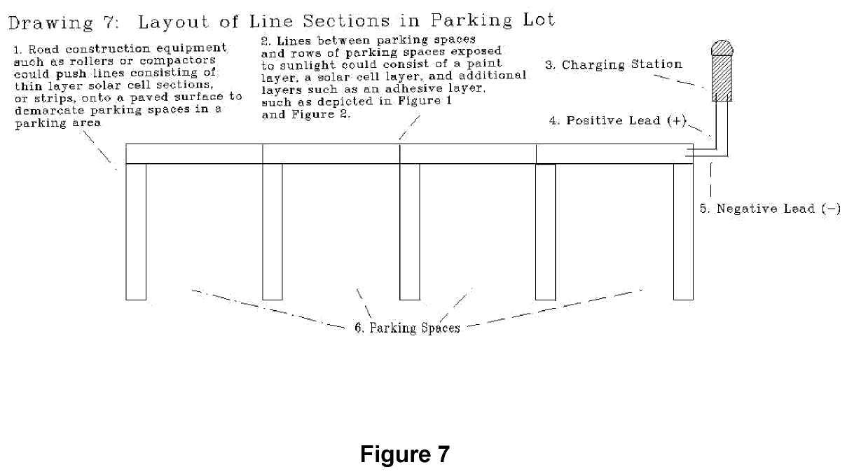

FIG. 7, that is, Drawing 7: Layout of Line Sections in Parking Lot, provides additional details for how multiple arrays of thin-layer solar cells, could be pressed by road construction rollers or compactors onto a parking space surface, as noted in Detail 1. Sections or strips of thin layer solar cells, manufactured as described in FIG. 1 and FIG. 2, could be joined congruently to form parking space lines, as noted in Detail 2. Such parking spaces are depicted in Detail 6. As depicted by Detail 4 and Detail 5, positive and negative leads from series-connected lines of thin layer solar cells could be connected to EV charging stations, such as depicted by Detail 3. As previously described, such lines of thin layer solar cells could contain series and hybrid series parallel electrical connections that could provide high DC voltage to EV charging stations for quick charging in parking lots or other parking areas.

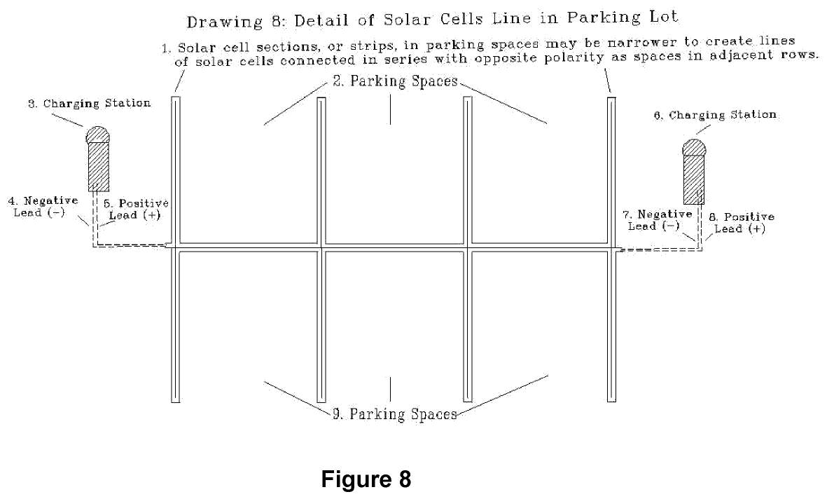

FIG. 8, that is, Drawing 8: Detail of Solar Cells Line in Parking Lot, depicts additional details of how lines of thin layer solar cell sections incorporating a material such as graphene, though not limited to this photovoltaic material, could be configured in rows of cells connected in series to an EV charging station to demarcate parking spaces such as depicted in Detail 2 and Detail 9. Negative and positive leads, depicted by Detail 4 and Detail 5, and Detail 7 and Detail 8, in adjacent facing rows could have opposite positive and negative polarity from leads in adjacent facing parallel rows, for series connection to EV charging stations, such as depicted by Detail 3 and Detail 6, though this would not be a requirement. As depicted, such an arrangement of thin-layer solar cells connected in series could create longer lines of solar cells in series to generate higher DC voltage provided to EV charging stations. Likewise, as noted in Detail 1, such a configuration of multiple rows of thin-layer solar cells could have characteristics such as narrower sections than strips of cells in a single row of such solar cells, to facilitate joining multiple solar cells in series to create higher voltages related additively to the length of the lines of thin layer solar cells forming parking space lines, etc.

Furthermore, at locations such as highway rest stops or pullovers, and lines in rows of parking spaces constructed of thin-layer solar cells, DC voltage provided to EV charging station batteries could be supplemented with DC power from road lane demarcation lines of thin-layer solar cells, such as depicted in FIG. 6. Likewise, when convenient at such locations, DC power supplied to EV charging stations, or a bank of batteries connected to charging stations, from parking space row lines, and in some cases road lane demarcation lines, could be supplemented with AC power from conventional power sources.

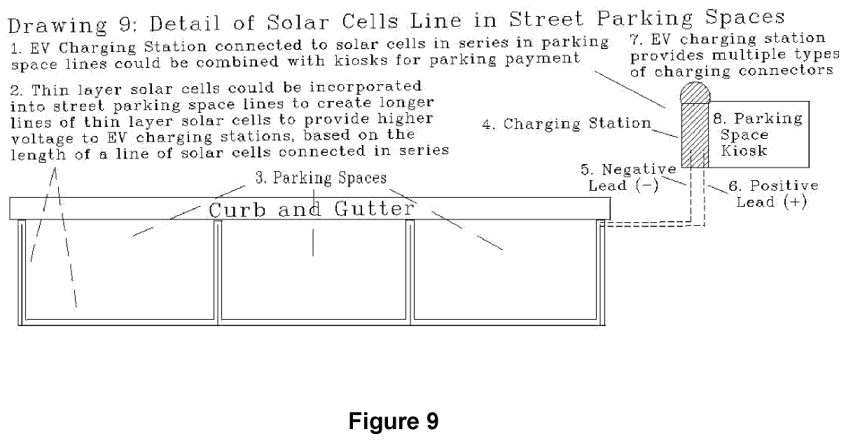

FIG. 9, that is, Drawing 10: Detail of Solar Cells Line in Street Parking Spaces, depicts additional details of how parking space demarcation lines constructed of thin-layer solar cells, incorporating a material such as graphene, though not limited to this photovoltaic material, could be implemented to create lines around street parking spaces, such as depicted in Detail 3. Also, as noted in Detail 2, strips of solar cells could be connected in parking space lines in a manner to create longer lines of contiguously series connected solar cells, to thereby generate higher DC voltage. Likewise, such parking space lines could be connected in series to EV charging stations, such as depicted as negative and positive leads, depicted, respectively, as Detail 5 and Detail 6, to a charging station, such as depicted by Detail 4, or a bank of batteries connected to charging stations. Detail 7 notes that EV charging stations for metered street parking could provide multiple connectors.

Additionally, as noted in Detail 1 and Detail 8, street parking with space line demarcations made of thin-layer solar cells could be connected to parking space kiosks that track monetary charges as well as provide EV battery charging power. Such kiosks could interface EV charging and parking space tracking with incorporated software. Additional features of parking spaces designated specifically for charging could include monetary charges related to battery charging time, such as time for fast charging and time limits related to the type of charging connection a vehicle uses. For example, this integration software in an EV charging station and parking kiosk could include sophisticated software features such a monetary charge related to the required charging time, for example, a lower charge for fast charging, such as Level 3 charging. Existing patents, such as Patent U.S. Pat. No. 6,081,205-A, provide detailed descriptions of EV charging stations that incorporate EV charging and parking meter charges. However, though other features, such as that multiple types of connectors could be provided by such charging and parking meter stations, are also described by such patents, despite their significant merit, such existing patents do not provide details such as noted in Detail 2, that is, that such kiosks could incorporate EV charging stations that are supplied power by lines of thin layer solar cells used to demarcate metered parking spaces, such as described in this patent application.

What is claimed:

1-5. (canceled)

6. A system of layered material for the construction of road lane lines, road lane separator lines, or parking space boundary lines, implemented by using equipment that has rollers and equipment that has compactors, which are used to flatten, compress, and smooth road or parking lot pavement, by applying pressure on this layered material toward a road or parking lot surface to flatten and compress this material and adhere this material on to a road or parking lot and, when pressed on to a road or parking lot and adhered on to a road or parking lot, indicate and provide road lane lines, road lane separator lines, or parking space boundary lines, comprising:
a top layer that is transparent to sunlight, or partially transparent to sunlight, contains one or more paint pigment colors, including white, red, blue, yellow or green or any other paint pigment color or any combination of paint pigment colors, in specific areas that are the width and length of road lane lines, road lane separator lines, or parking space boundary lines for which this top layer indicates and provides road lane lines, road lane separator lines, or parking space boundary lines and that, when flattened and pressed on to a road or parking lot surface and adhered on to a road or parking lot by equipment that has rollers and equipment that has compactors, indicates and provides road lane lines, road lane separator lines, or parking space boundary lines;
below the top layer or incorporated into the top layer, a photovoltaic layer containing thin-layer solar cells that, when flattened and pressed on to a road or parking lot surface and adhered on to a road or parking lot by equipment that has rollers and equipment that has compactors, is exposed to sunlight when sunlight is available to the road or parking lot, on which this material is flattened and pressed on to and adhered on to, to indicate and provide road lane lines, road lane separator lines, or parking space boundary lines; and
a bottom layer that contains an adhesive substance on its bottom side or on both its top and bottom sides, is as wide as all other layers above this layer and, which when flattened and pressed on to a road or parking lot top surface by applying pressure toward a road or parking surface by using equipment that has rollers and equipment that has compactors, is adjacent on its bottom side to a road, parking space, or parking lot surface and adheres on to a road or parking surface.

7. The system described in claim 6 for which one or two rollers, or any combination of rollers containing more than one roller, are used to manufacture the described layered material by pressing layers together to form congruently joined layered material.

8. The system described in claim 6 is flattened and compressed on to a road or parking lot surface and adhered on to a road or parking lot surface by equipment that has rollers and equipment that has compactors, which flatten, compress, and smooth the surface of road or parking lot pavement, by:
orienting a transparent or partially transparent top layer that, when flattened and compressed on to a road or parking lot surface by equipment that has rollers and equipment that has compactors, is above a photovoltaic layer containing thin layer solar cells, or is incorporated into a photovoltaic layer containing thin layer solar cells, and is above a bottom layer containing an adhesive material;
orienting a photovoltaic layer containing thin layer solar cells that, when flattened and compressed on to a road or parking lot surface by equipment that has rollers and equipment that has compactors, faces upward toward sunlight, is below or incorporated into a transparent or partially transparent top layer, and is above a bottom layer containing an adhesive material; and
orienting an adhesive bottom layer that, when flattened and compressed on to a road or parking lot surface by equipment that has rollers and equipment that has compactors, is below a transparent or partially transparent top layer, is below or incorporated into a photovoltaic layer containing thin layer solar cells, is adjacent to a road or parking lot surface, and adheres on to a road or parking lot surface when pressure is applied toward a road or parking lot surface by equipment that has rollers and equipment that has compactors.

9. The system described in claim 6 is placed on a road or parking lot surface to provide and indicate electrically contiguous lines of solar cells by using equipment that has rollers and equipment that has compactors, which are used to flatten, compress, and smooth road or parking lot pavement, to join wires together from adjacent segments of road or parking space line material so that:
negative to positive leads or positive to negative leads from solar cells in adjacent sections of thin layer solar cells are joined to provide series configurations of electrical circuits; and
negative to negative leads or positive to positive leads from solar cells in adjacent sections of thin layer solar cells are joined to provide parallel configurations of electrical circuits.

10. The system described in claim 6 is placed on a road or parking lot surface by joining segments of road lane lines, road lane separator lines, or parking space boundary lines, that contain thin layer solar cells, so that the conductivity and durability of wires between joined adjacent segments containing solar cells is increased or enhanced by the durability and conductivity characteristics of photovoltaic material in thin layer solar cells, by using equipment that has rollers and equipment that has compactors, which are used to flatten, compress, and smooth road or parking lot pavement, to press photovoltaic material in thin layer solar cells on to wires connecting adjacent segments that contain thin layer solar cells.

11. The system described in claim 6 is placed on a road or parking lot surface to provide electrically contiguous road lane lines, road lane separator lines, or parking space boundary lines by using equipment that has rollers and equipment that has compactors, which are used to flatten, compress, and smooth road or parking lot pavement, to join adjacent segments of color-imbued material together.
